(19) United States
(12) Patent Application Publication
(10) Pub. No.: US 2016/0335160 A1
(43) Pub. Date: Nov. 17, 2016

(54) MEMORY DEVICE WITH SPECULATED BIT FLIP THRESHOLD

(71) Applicant: EMPIRE TECHNOLOGY DEVELOPMENT LLC, Wilmington (DE)

(72) Inventor: TONG ZHANG, (US)

(73) Assignee: EMPIRE TECHNOLOGY DEVELOPMENT LLC, WILMINGTON, DE (US)

(21) Appl. No.: 15/107,751

(22) PCT Filed: Apr. 3, 2014
(86) PCT No.: PCT/US14/32818

§ 371 Date: Jun. 23, 2016

(51) Int. Cl. G06F 11/10; H03M 13/11; G11C 29/50

(52) U.S. Cl. CPC G06F 11/1096; G11C 29/50004; H03M 13/1177; G06F 2211/109; G11C 2029/5004

(57) ABSTRACT

Technologies are described for systems, devices and methods effective to decode data read from a memory. Coded data may be stored in a buffer. A parity check syndrome vector may be calculated by a bit flip module, based on the coded data and based on a parity matrix. The parity check syndrome vector may include unsatisfied bits. The parity check syndrome vector may be stored in the buffer. The bit flip module may calculate a speculated bit flip threshold based on a feature of the parity matrix. The bit flip module may determine, based on the parity check syndrome vector, a number of unsatisfied parity checks participated in by a particular bit of the coded data. The bit flip module may flip the particular bit in response to the number of unsatisfied parity checks for the particular bit being greater than or equal to the speculated bit flip threshold.

### BACKGROUND

Unless otherwise indicated herein, the materials described in this section are not prior art to the claims in this application and are not admitted to be prior art by inclusion in this section.

Solid state data storage devices may be used in an information technology infrastructure to handle intensive data access workloads. A solid state storage device may include a multitude of transistors controlled by a solid state memory controller. Each transistor may be configured to store one bit of data. The solid state memory controller may be configured to control access to data stored within transistors. Transistors may have a limited number of program/erase cycles before such transistors degrade. Error correction code may be used to correct errors stored in and/or read from transistors in solid state memory.

### SUMMARY

In one example, methods to decode data read from a memory are generally described. The methods may include, by a processor, storing coded data in a buffer. The methods may further include, calculating, by a bit flip module, a parity check syndrome vector based on the coded data and based on a parity check matrix. The parity check syndrome vector may include unsatisfied bits. The methods may further include, by a processor, storing the parity check syndrome vector in the buffer. The methods may further include, by the bit flip module, calculating a speculated bit flip threshold based on a feature of the parity check matrix. The methods may further include, by the bit flip module, determining, based on the parity check syndrome vector, a number of unsatisfied parity checks participated in by a particular bit of the coded data. The methods may further include, by the bit flip module, flipping the particular bit in response to the number of unsatisfied parity checks for the particular bit being greater than or equal to the speculated bit flip threshold.

In one example, memory controllers are generally described. The memory controllers may include a bit flip module. The memory controllers may further include a buffer configured to be in communication with the bit flip module. The buffer may be configured to store coded data. The bit flip module may be effective to calculate a parity check syndrome vector based on the coded data stored in the buffer and based on a parity check matrix. The parity check syndrome vector may include unsatisfied bits. The bit flip module may be further effective to calculate a speculated bit flip threshold based on a feature of the parity check matrix. The bit flip module may be further effective to determine, based on the parity check syndrome vector, a number of unsatisfied parity checks participated in by a particular bit of the coded data. The bit flip module may be further effective to flip the particular bit in response to the number of unsatisfied parity checks for the particular bit being greater than or equal to the speculated bit flip threshold.

In one example, memory devices are generally described. The memory devices may include a bit flip module. The memory devices may further include a buffer configured to be in communication with the bit flip module. The memory devices may further include a memory chip configured to be in communication with the bit flip module. The memory chips may be effective to store coded data. The bit flip module may be effective to receive the coded data from the memory chip. The bit flip module may be further effective to calculate a parity check syndrome vector based on the coded data and based on a parity check matrix. The parity check syndrome vector may include indications of unsatisfied rows of the parity check matrix. The bit flip module may be further effective to store the parity check syndrome vector in the buffer. The bit flip module may be further effective to calculate a speculated bit flipping threshold based on a feature of the parity check matrix. The bit flip module may be further effective to determine, based on the parity check syndrome vector, a number of unsatisfied parity checks participated in by a particular bit of the coded data. The bit flip module may be further effective to flip the particular bit in response to the number of unsatisfied parity checks for the particular bit being greater than or equal to the speculated bit flip threshold.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGS.

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

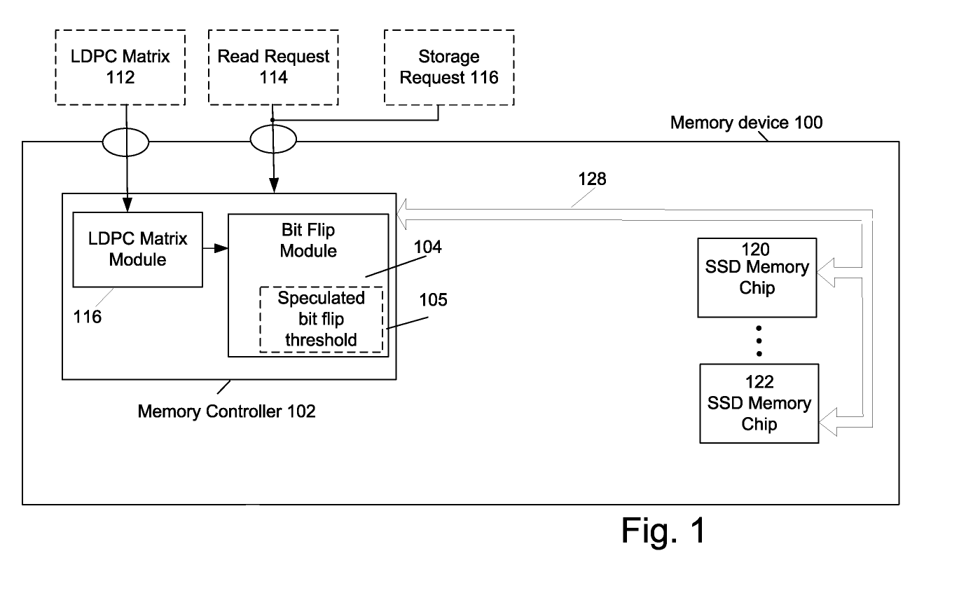

FIG. 1 illustrates an example system that can be utilized to implement a memory device with speculated bit flip threshold;

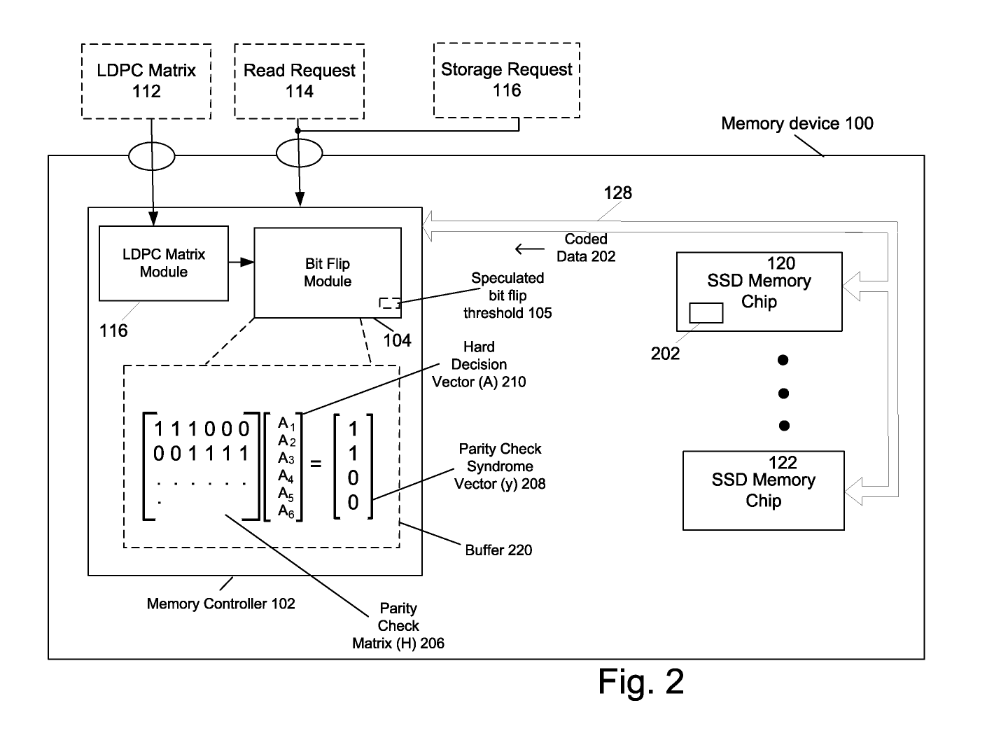

FIG. 2 depicts the example system of FIG. 1 illustrating additional details relating to a bit flip module;

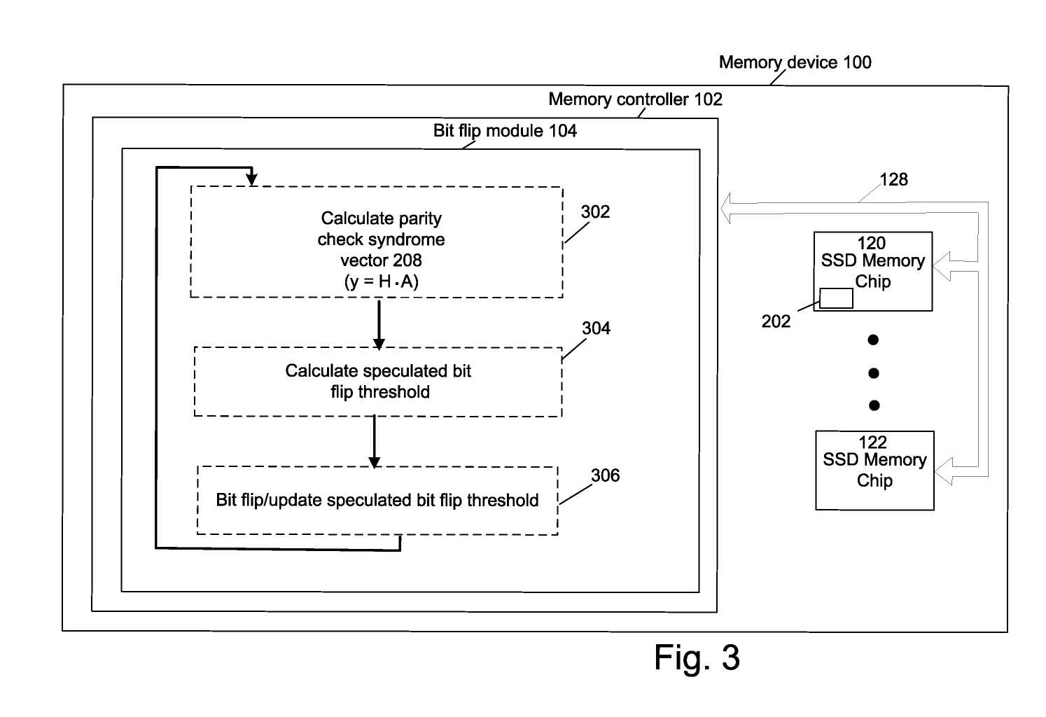

FIG. 3 depicts the example system of FIG. 1, illustrating an example relating to implementation of a bit flip module with speculated bit flip threshold;

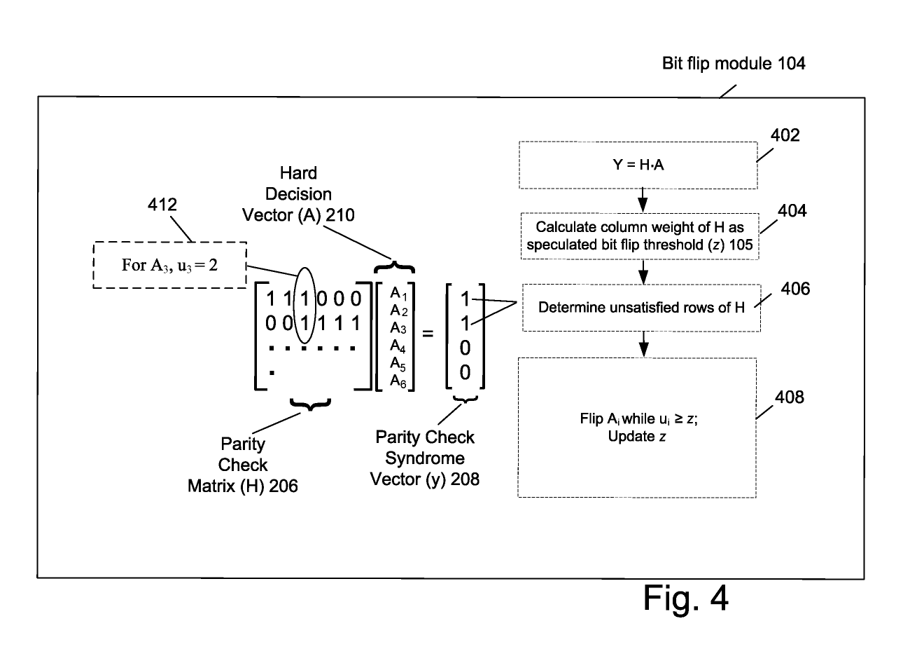

FIG. 4 depicts the example system of FIG. 1, illustrating an example relating to a low density parity check using bit flipping;

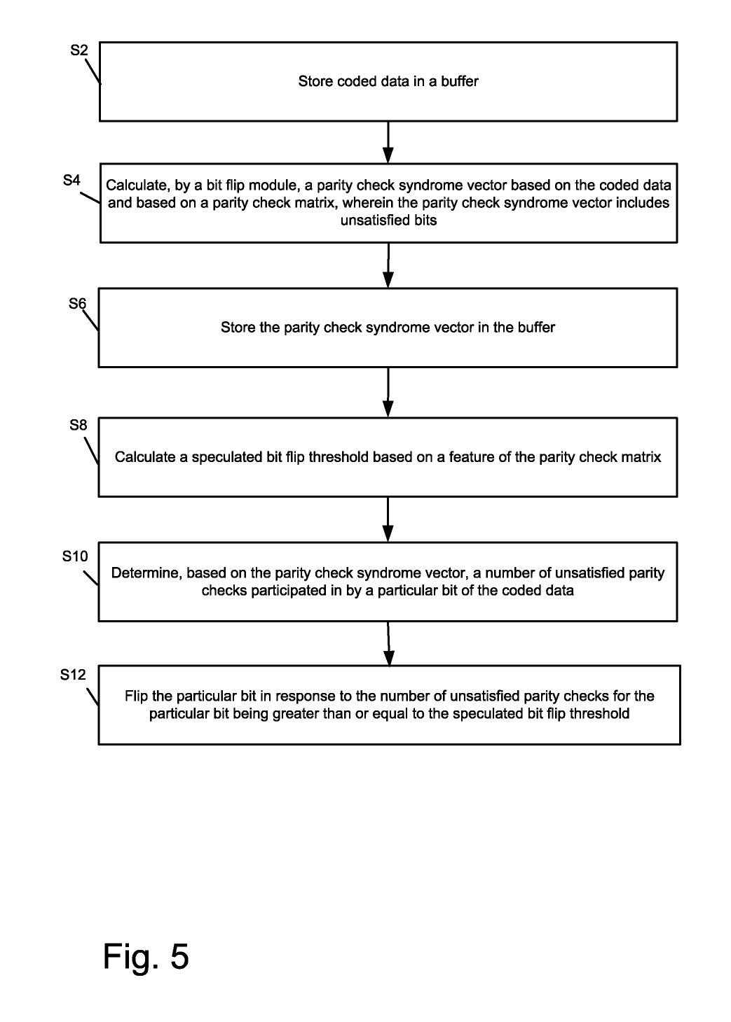

FIG. 5 depicts a flow diagram for an example process to implement a memory device with speculated bit flip threshold;

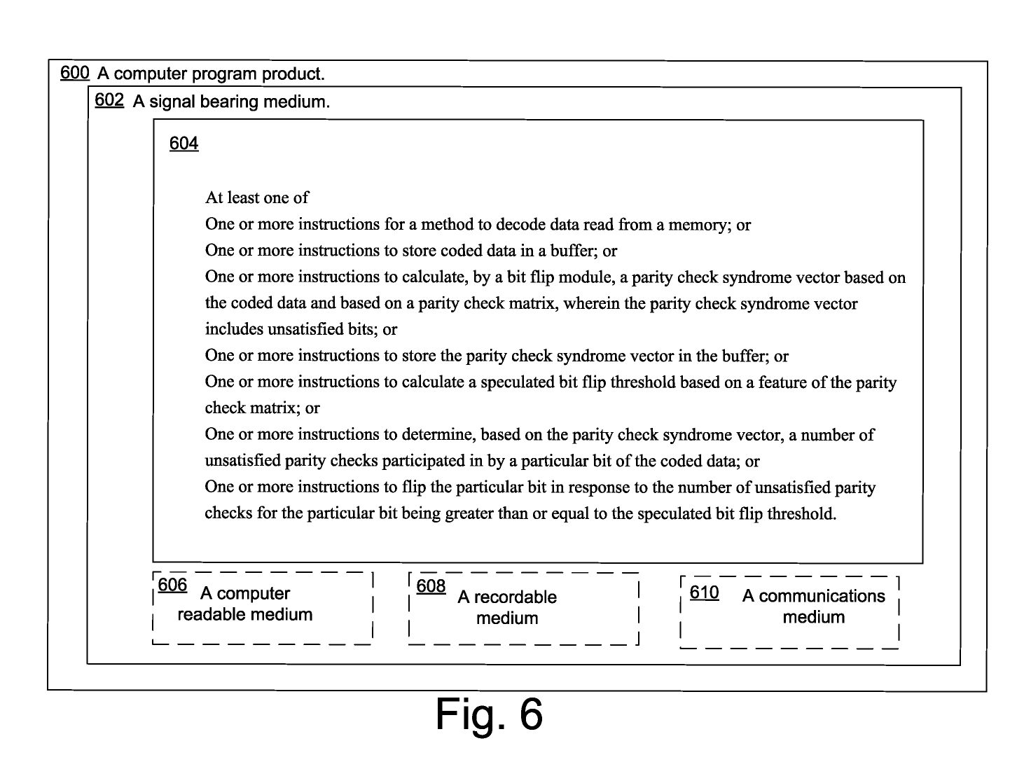

FIG. 6 illustrates an example computer program product that can be utilized to implement a memory device with speculated bit flip threshold; and

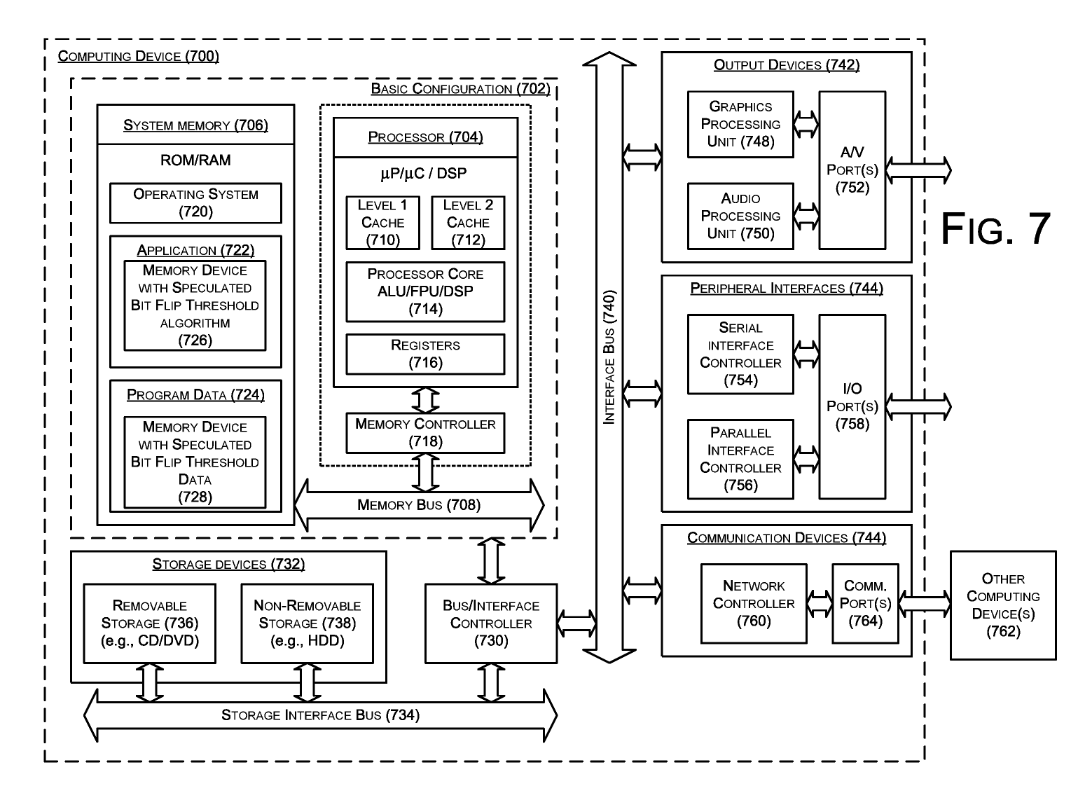

FIG. 7 is a block diagram illustrating an example computing device that is arranged to implement a memory device with speculated bit flip threshold; all arranged according to at least some embodiments described herein.

### DETAILED DESCRIPTION

In the following detailed description, reference is made to the accompanying drawings, which form a part hereof In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. The aspects of the present disclosure, as generally described herein, and illustrated in the drawings, can be arranged, substituted, combined, separated, and designed in a wide variety of different configurations, all of which are explicitly contemplated herein.

This disclosure is generally drawn to, inter alia, methods, apparatus, systems, devices, and computer program products related to a memory device with speculated bit flip threshold.

Briefly stated, technologies are generally described for systems, devices and methods effective to decode data read from a memory. Coded data may be stored in a buffer. A parity check syndrome vector may be calculated by a bit flip module, based on the coded data and based on a parity check matrix. The parity check syndrome vector may include unsatisfied bits. The parity check syndrome vector may be stored in the buffer. The bit flip module may calculate a speculated bit flip threshold based on a feature of the parity check matrix. The bit flip module may determine, based on the parity check syndrome vector, a number of unsatisfied parity checks participated in by a particular bit of the coded data. The bit flip module may flip the particular bit in response to the number of unsatisfied parity checks for the particular bit being greater than or equal to the speculated bit flip threshold.

FIG. 1 illustrates an example system that can be utilized to implement a memory device with speculated bit flip threshold, arranged in accordance with at least some embodiments described herein. An example memory device 100 may include a memory controller 102. Memory device 100 may include one or more chips. Memory controller 102 may be a dedicated chip or may be integrated into another chip, such as a microprocessor. Memory controller 102 may process or control reads of and/or writes to one or more solid state drive (“SSD”) memory chips 120, 122. SSD memory chips 120, 122 may be, for example, solid state or flash memory where transistors are configured in a NAND or NOR configuration. Memory controller 102 may be configured in communication with or otherwise coupled to SSD memory chips 120, 122 by a system link 128. System link 128 may be, for example, a bus or other form of communication within memory device 100.

Memory controller 102 may include a low density parity check (“LDPC”) matrix module 116. LDPC matrix module 116 may be embodied in hardware and/or a combination of hardware and instructions executable on the hardware. For example, LDPC matrix module 116 may be instantiated via an application specific integrated circuit (ASIC) and/or a field programmable gate array (FPGA). LDPC matrix module 116 may be configured to receive an LDPC matrix 112. LDPC matrix 112 may specify one or more sparse matrices that may be used to perform an error correction code on data processed by memory controller 102. The majority of values included in sparse LDPC matrix 112 may be zero. LDPC matrix 112 may be generated by LDPC matrix module 116 or may be input by a user or by another device associated with memory device 100.

Memory controller 102 may include a bit flip module 104 that may calculate a speculated bit flip threshold 105. Bit flip module 104 may be embodied in hardware and/or a combination of hardware and instructions executable on the hardware. For example, bit flip module 104 may be instantiated via an ASIC and/or an FPGA. Bit flip module 104 may be configured to be in communication with or otherwise coupled to LDPC matrix module 116. In one example, bit flip module 104 and LDPC matrix module 116 may be instantiated together in an ASIC or FPGA design. As will be discussed in further detail below, bit flip module 104 may be configured to facilitate error correction on data read from SSD memory chips 120, 122. Bit flip module 104 may be further configured to calculate speculated bit flip threshold 105 based upon a feature of LDPC matrix 112. Bit flip module 104 and LDPC matrix module 116 may be located in memory controller 102 or on one or more separate chips.

In an example of operation, memory controller 102 may receive a read request 114. Read request 114 may be a request to read data stored in at least one of SSD memory chip 120 and/or SSD memory chip 122. Data stored in SSD memory chips 120 and/or 122 may be coded. Memory controller 102 may also be configured to receive storage request 116. Storage request 116 may be a request for memory controller 102 to store data in at least one of SSD memory chip 120 and SSD memory chip 122. In processing read request 114, memory controller 102 may use bit flip module 104 to calculate speculated bit flip threshold 105 to perform error correction on data read from SSD memory chip 120 and/or 122.

FIG. 2 depicts the example system of FIG. 1 illustrating additional details relating to a bit flip module, arranged accordance with at least some embodiments described herein. Those components in FIG. 2 that are labeled identically to components of FIG. 1 will not be described again for the purposes of clarity and brevity.

In an example, memory controller 102 may receive read request 114. Read request 114 may be, for example, a request for coded data 202 stored in SSD memory chip 120. In processing read request 114, memory controller 102 may receive coded data 202 from SSD memory chip 120. Memory controller 102 may store coded data 202 in a buffer 220. Buffer 220 may be, for example, a memory or other storage device associated with memory controller 102. In another example, buffer 220 may be associated with bit flip module 104. Coded data 202 may be provided to bit flip module 104 as hard decision vector (“A”) 210. Hard decision vector 210 may be a binary code associated with coded data 202. In one example, hard decision vector 210 may include the bits in coded data 202 as read from transistors in SSD memory chip 120. In another example, hard decision vector 210 may be a binary representation of coded data 202. Hard decision vector 210 may be encrypted. In an example, with reference to FIG. 2, hard decision vector 210 may be represented as a 6×1 matrix “A” (including values A₁, A₂, A₃, A₄, A₅, A₆).

LDPC matrix module 116 may be configured to provide a parity check matrix (“H”) 206 to bit flip module 104. Parity check matrix 206 may be a sparse binary parity check matrix that may be used to perform error correction on coded data 202 read from and/or written to SSD memory chips 120, 122. Parity check matrix 206 may be generated and/or may be input by a user or specified by a different device. Parity check matrix 206 may include the same number of columns as the number of rows in hard decision vector 210. As depicted in FIG. 2, bit flip module 104 may determine a dot product of parity check matrix “H” 206 and hard decision vector “A” 210. The resultant vector may be parity check syndrome vector (“y”) 208. Parity check syndrome vector 208 may be stored in buffer 220. Parity check syndrome vector 208 may be the dot product of parity check matrix 206 and hard decision vector 210 (e.g., y=H·A). Determining the dot product of parity check matrix “H” 206 and hard decision vector (“A”) 210 to determine parity check syndrome vector (“y”) 208 may be referred to as performing a parity check.

If all binary values of parity check syndrome vector 208 are zero, bit flip module 104 may determine that hard decision vector 210 may be a valid codeword. A determination of a valid codeword may indicate that coded data 202 has been read without error from SSD memory chip 120. Conversely, when parity check syndrome vector 208 includes a binary value of “1,” hard decision vector 210 may be a non-valid codeword. Binary values of “1” included in parity check syndrome vector 208 may be unsatisfied bits of parity check syndrome vector 208. As will be described in more detail below, when hard decision vector 210 is determined to be a non-valid codeword, bit flip module 104 may be configured to flip one or more bits of hard decision vector 210 to produce decoded data. Bit flip module 104 may determine a number of bits to flip hard decision vector 210 based on a number of unsatisfied bits in parity check syndrome vector 208 and a feature of parity check matrix 206. After flipping one or more bits of hard decision vector 210 to produce decoded data, bit flip module 104 may store the decoded data in buffer 220. Flipping one or more bits of hard decision vector 210 to decode hard decision vector 210 may produce decoded data that includes a valid codeword.

In an example, with reference to FIG. 2, hard decision vector 210 (including A₁-A₆) may have values of [1 1 1 0 0 0]. The dot product of the example parity check matrix 206 and hard decision vector 210 may result in parity check syndrome vector 208 having the values [1 1 0 0]. The “1” values in the example parity check syndrome vector 208 may indicate that rows 1 and 2 of parity check matrix 206 were not satisfied during the parity check. Bit flip module 104 may be configured to flip one or more bits of hard decision vector 210 based on speculated bit flip threshold 105. As will be discussed in further detail below, speculated bit flip threshold 105 may be a number that is used for comparison with the number of unsatisfied parity checks participated in by bits of hard decision vector 210 or coded data 202. Speculated bit flip threshold 105 may be determined based on a feature of parity check matrix 206. For example, speculated bit flip threshold 105 may be determined based on the column weight of parity check matrix 206. The column weight of parity check matrix 206 may be, for example, the number of “1s” in each column of parity check matrix 206.

Bit flip module 104 may determine the number of unsatisfied parity checks participated in by bits of hard decision vector 210 or coded data 202. The number of unsatisfied parity checks participated in by bits in hard decision vector 210 may be indicated by bits in parity check syndrome vector 208 and may be the number of “1s” in an unsatisfied row of parity check matrix 206. An unsatisfied row of parity check matrix 206 may be identified by the presence of a “1” in parity check syndrome vector 208 at a position corresponding to a row of parity check matrix 206. If the number of unsatisfied parity checks participated in by a particular bit of hard decision vector 210 is greater than or equal to speculated flip threshold 105, bit flip decoding module 104 may flip that particular bit. After making a determination on whether to flip the particular bit, bit flip module 104 may continue to determine numbers of unsatisfied parity checks for remaining bits of hard decision vector 210.

If at least one bit Aᵢ in hard decision vector 210 participates in a number of unsatisfied parity checks that is greater than speculated flip threshold 105, bit flip module 104 may increase speculated flip threshold 105 to the number of unsatisfied parity checks participated in by bit Aᵢ, and may also flip bit Aᵢ. For example, speculated flip threshold 105 may initially be calculated as “4”. The second bit in hard decision vector 210 may participate in 5 unsatisfied parity checks. Bit flip module 104 may flip the second bit in hard decision vector 210 and increase the speculated flip threshold to 5 for subsequent iterations including subsequent parity checks. In an example, flipping a bit in hard decision vector 210 may produce decoded data to be used in subsequent parity checks. Parity checks may be performed until parity check syndrome vector 208 includes only “0” values.

In comparison, if all bits in hard decision vector 210 participate in a number of unsatisfied parity checks that is less than speculated bit flip threshold 105, bit flip module 104 may update speculated bit flip threshold 105 to the number of unsatisfied parity checks participated in by the bit in hard decision vector 210 that participated in the greatest number of unsatisfied parity checks. For example, speculated flip threshold 105 may initially be “4”. If the highest number of unsatisfied parity checks participated in by any bit of hard decision vector 210 is “2”, bit flip module 104 may decrease speculated bit flip threshold 105 to “2” for subsequent iterations in calculating parity check syndrome vector 208.

FIG. 3 depicts the example system of FIG. 1, illustrating an example relating to implementation of a bit flip module with speculated bit flip threshold, arranged in accordance with at least some embodiments described herein. Those components in FIG. 3 that are labeled identically to components of FIGS. 1 and 2 will not be described again for the purposes of clarity and brevity.

Bit flip module 104 may perform certain operations on coded data 202 read from SSD memory chip 120. An example process may include one or more operations, actions, or functions as illustrated by one or more of blocks 302, 304, 306. Although illustrated as discrete blocks, various blocks may be divided into additional blocks, combined into fewer blocks, supplemented with other blocks, or eliminated, depending on the particular implementation. At block 302, “Calculate parity check syndrome vector 208 (y=H·A),” bit flip module 104 may be configured to calculate parity check syndrome vector 208. As discussed previously, parity check syndrome vector 208 may be calculated by taking the dot product of parity check matrix 206 and hard decision vector 210 (e.g., y=H·A). If parity check syndrome vector 208 indicates that hard decision vector 210 is a valid codeword (e.g., parity check syndrome vector includes only zeroes), coded data 202 may have been successfully read from SSD memory chip 120. If parity check syndrome vector 208 indicates that hard decision vector 210 is not a valid codeword, bit flip module 104 may proceed to block 304.

At block 304, “Calculate speculated bit flip threshold,” which may follow block 302, bit flip module 104 may calculate speculated bit flip threshold 105. In an example, bit flip module 104 may calculate speculated bit flip threshold 105 based on a feature such as the column weight of parity check matrix 206. After calculating speculated bit flip threshold 105, bit flip module 104 may proceed to block 306.

At block 306, “Bit flip/update speculated bit flip threshold,” which may follow block 304, bit flip module 104 may perform a bit flip. Based on parity check syndrome vector 208, bit flip module 104 may determine that one or more rows of parity check matrix 206 were not satisfied during the parity check where parity check syndrome vector 208 was calculated.

Bit flip module 104 may update speculated bit flip threshold 105 based on the number of unsatisfied parity checks. Following block 306, bit flip module 104 may return to block 302 for a second iteration of parity checks. Iterations of parity checks may continue until parity check syndrome vector 208 includes only “0” values.

FIG. 4 depicts the example system of FIG. 1, illustrating an example relating to a low density parity check using bit flipping, arranged in accordance with at least some embodiments described herein. Those components in FIG. 4 that are labeled identically to components of FIGS. 1, 2 and 3 will not be described again for the purposes of clarity and brevity.

Bit flip module 104 may perform certain operations on coded data 202 read from SSD memory chip 120. An example process may include one or more operations, actions, or functions as illustrated by one or more of blocks 402, 404, 406, 408. Although illustrated as discrete blocks, various blocks may be divided into additional blocks, combined into fewer blocks, supplemented with other blocks, or eliminated, depending on the particular implementation.

In the example depicted in FIG. 4, at block 402, (“y=HA”), bit flip module 104 may calculate parity check syndrome vector 208 by taking the dot product of parity check matrix 206 and hard decision vector 210 (e.g., y=WA). In the example, as shown at 412, parity check syndrome vector 208 may be [1 1 0 0], where the “1”s indicate that hard decision vector 210 is not a valid codeword. At block 404, “Calculate column weight of H as speculated bit flip threshold (z) 105,” which may follow block 402, the column weight of parity check matrix 206 may be calculated as speculated bit flip threshold 105 (“z”). In the example, as shown at 412, parity check matrix 206 may have a column weight of 2 because the column weight of parity check matrix 206, or the column A₃ with the most number of “1”s, includes two “1”s. Accordingly, speculated bit flip threshold 204 may be calculated as “2.” At block 406, “Determine unsatisfied rows of H,” which may follow block 404, parity check syndrome vector 208 may be used to determine the unsatisfied rows of parity check matrix 206. Rows of parity check syndrome vector 208 with a value of “1” may indicate that the corresponding row of parity check matrix 206 was not satisfied during the parity check. In the example, as the first two rows of parity check syndrome vector 208 include a value of “1,” bit flip module 104 may determine that the first two rows of parity check matrix 206 were not satisfied during the parity check.

At block 408, “Flip Aᵢ while uᵢ≧z; Update z” which may follow block 406, bit flip module 104 may determine the number of unsatisfied parity checks (uᵢ) for each bit Aᵢ of hard decision vector 210. For each unsatisfied row of parity check syndrome vector 208, bit flip module 104 may count the number of “1s” for each column of parity check matrix 206. If the number of 1s in a particular column equals or exceeds speculated bit flip threshold 105, the bit Aᵢ in hard decision vector 210 corresponding to the particular column may be flipped by bit flip module 104. In the example, bit flip module 104 may count one “1” for columns 1, 2, 4, 5 and 6 of the unsatisfied rows of parity check matrix 206. Therefore, uᵢ for bits A₁ A₂, A₄, A₅, and A₆ may be equal to 1. Bit flip module 104 may count two “1”s for column 3 of parity check matrix 206. Therefore u₃ for bit A₃ may equal 2.

At block 408, bit flip module 104 may flip bits of hard decision vector 210 when uᵢ for bit Aᵢ is greater than or equal to speculated bit flip threshold 105. If uᵢ is greater than bit flip threshold 105, bit flip module 104 may update bit flip threshold 105 with the bit flip. In the example, as speculated bit flip threshold 105 is “2,” bit A₃ may be flipped because u₃=2.

In a second example, speculated bit flip threshold 105 may be “4.” In the second example, bit A₅ may participate in 6 unsatisfied parity checks (u₅=6). Bit flip module 104 may flip bit A₅ and update bit flip threshold 105 to a value of “6” for subsequent iterations. In a third example, bit flip threshold 105 may be “4.” The bit A₁ that participated in the greatest number of unsatisfied parity checks may have participated in 2 unsatisfied parity checks (u₁=2). In the third example, no bit may be flipped but bit flip module 104 may decrease bit flip threshold to “2” for subsequent iterations.

Among other possible features, a system in accordance with the disclosure may efficiently correct errors read from solid state memory using low density parity check techniques. In an example, a bit flip threshold may be updated with a bit being flipped. Updates of the bit flip threshold may improve efficiency and speed of error correction because the bit flip module need not process all bits before updating the bit flip threshold. Additionally, initial calculation of the speculated bit flip threshold may avoid a global search for the maximum number of unsatisfied parity checks participated in by each bit of a hard decision vector. Initial calculation of the speculated bit flip threshold may therefore also improve speed and efficiency of low density parity check error correction. Speed and power consumption in a SSD may be reduced. The latency of decoding operations may be reduced because a search of the parity check matrix for the bit flipping threshold need not be performed. As the sparse parity check matrix used in LDPC decoding tends to have four, five or six “1”s, for example, calculating a speculated bit flipping threshold may work efficiently.

FIG. 5 depicts a flow diagram for example processes to implement a memory device with speculated bit flip threshold arranged in accordance with at least some embodiments described herein. In some examples, the process in FIG. 5 could be implemented using memory device 100 discussed above and could be used to implement a memory device with speculated bit flip threshold. An example process may include one or more operations, actions, or functions as illustrated by one or more of blocks S2, S4, S6, S8, S10 and/or S12. Although illustrated as discrete blocks, various blocks may be divided into additional blocks, combined into fewer blocks, or eliminated, depending on the desired implementation. The blocks may be supplemented with additional blocks representing other operations, actions or functions. The process in FIG. 5 may be used by a memory device that includes a bit flip module. The bit flip module may be configured in communication with one or more solid state flash memory chips.

Processing may begin at block S2, “Store the coded data in a buffer.” For example, at block S2, memory controller 102 may store coded data in a buffer, such as for example, buffer 220 of bit flip module 104.

Processing may continue from block S2 to block S4, “Calculate, by a bit flip module, a parity check syndrome vector based on the coded data and based on a parity check matrix, wherein the parity check syndrome vector includes unsatisfied bits.” For example, at block S4, bit flip module 104 may calculate parity check syndrome vector 208. Parity check syndrome vector 208 may be calculated based on the coded data and based on a parity check matrix (e.g., parity check matrix 206). Parity check syndrome vector 208 may include unsatisfied bits.

Processing may continue from block S4 to block S6, “Store the parity check syndrome vector in the buffer.” For example, at block S6, bit flip module 104 may store parity check syndrome vector 208 in buffer 220. 100391 Processing may continue from block S6 to block S8, “Calculate a speculated bit flip threshold based on a feature of the parity check matrix.” For example, at block S8, bit flip module 104 may calculate speculated bit flip threshold 105 based on a feature of parity check matrix 206. The feature of the parity check matrix may include a column weight.

Processing may continue from block S8 to block S10, “Determine, based on the parity check syndrome vector, a number of unsatisfied parity checks participated in by a particular bit of the coded data.” At block S10, bit flip module 104 may determine a number of unsatisfied parity checks uᵢ participated in by a particular bit of the coded data based on parity check syndrome vector 206. Bit flip module 104 may update bit flip threshold 105 to produce another bit flip threshold based on a number of unsatisfied parity checks participated in by the coded data. Updating the bit flip threshold may include bit flip module 104 increasing the bit flip threshold in response to the number of unsatisfied parity checks participated in by the particular bit being greater than the bit flip threshold. Updating the bit flip threshold may include bit flip module 104 decreasing the bit flip threshold in response to the number of unsatisfied parity checks being less than the speculated bit flip threshold. Determining the number of unsatisfied parity checks participated in by the particular bit may include bit flip module 104 counting binary 1 values in unsatisfied rows of the parity check matrix. Bit flip module 104 may determine the unsatisfied rows of the parity check matrix based on the parity check syndrome vector.

Processing may continue from block S10 to block S12, “Flip the particular bit in response to the number of unsatisfied parity checks for the particular bit being greater than or equal to the speculated bit flip threshold.” At block S12, bit flip module 104 may flip the particular bit in response to the number of unsatisfied parity checks for the particular bit being greater than or equal to the speculated bit flip threshold. After flipping the particular bit, bit flip module 104 may update the bit flip threshold based on a number of unsatisfied parity checks participated in by the particular bit.

FIG. 6 illustrates an example computer program product 600 that can be utilized to implement a memory device with speculated bit flip threshold, arranged in accordance with at least some embodiments described herein. Program product 600 may include a signal bearing medium 602. Signal bearing medium 602 may include one or more instructions 604 that, in response to execution by, for example, a processor, may provide the functionality and features described above with respect to FIGS. 1-5. Thus, for example, referring to memory device 100, memory controller 102 may undertake one or more of the blocks shown in FIG. 5 and/or in the other Figures in response to execution of instructions 604 conveyed to memory device 100 by medium 602.

In some implementations, signal bearing medium 602 may encompass a non-transitory computer-readable medium 606, such as, but not limited to, a hard disk drive, a Compact Disc (CD), a Digital Video Disk (DVD), a digital tape, memory, etc. In some implementations, signal bearing medium 602 may encompass a recordable medium 608, such as, but not limited to, memory, read/write (R/W) CDs, R/W DVDs, etc. In some implementations, signal bearing medium 602 may encompass a communications medium 610, such as, but not limited to, a digital and/or an analog communication medium (e.g., a fiber optic cable, a waveguide, a wired communications link, a wireless communication link, etc.). Thus, for example, program product 600 may be conveyed to one or more modules of the memory device 100 by an RF signal bearing medium 602, where the signal bearing medium 602 is conveyed by a wireless communications medium 610 (e.g., a wireless communications medium conforming with the IEEE 802.11 standard).

FIG. 7 is a block diagram illustrating an example computing device 700 that is arranged to implement memory device with speculated bit flip threshold, arranged in accordance with at least some embodiments described herein. In a very basic configuration 702, computing device 700 typically includes one or more processors 704 and a system memory 706. A memory bus 708 may be used for communicating between processor 704 and system memory 706.

Depending on the desired configuration, processor 704 (which may be used to implement at least some of the components previously discussed above, such as bit flip module 104) may be of any type including but not limited to a microprocessor (μP), a microcontroller (μC), a digital signal processor (DSP), or any combination thereof. Processor 704 may include one more levels of caching, such as a level one cache 710 and a level two cache 712, a processor core 714, and registers 716. An example processor core 714 may include an arithmetic logic unit (ALU), a floating point unit (FPU), a digital signal processing core (DSP Core), or any combination thereof An example memory controller 718 may also be used with processor 704, or in some implementations memory controller 718 may be an internal part of processor 704. Memory controller 718 may be used to implement memory controller 102 of FIG. 1 in one embodiment.

Depending on the desired configuration, system memory 706 (which may be used to implement SSD memory chip 120 or 122) may be of any type including but not limited to volatile memory (such as RAM), non-volatile memory (such as ROM, flash memory, etc.) or any combination thereof System memory 706 may include an operating system 720, one or more applications 722, one or more programmable circuits 766 and program data 724. Application 722 may include a memory device with speculated bit flip threshold algorithm 726 that is arranged to perform the functions and operations as described herein including those described with respect to FIGS. 1-6 in connection with memory device 100. Program data 724 may include memory device with speculated bit flip threshold data 728 that may be useful to implement a memory device with speculated bit flip threshold as is described herein. In some embodiments, application 722 may be arranged to operate with program data 724 in cooperation with operating system 720 such that a memory device with speculated bit flip threshold may be provided. This described basic configuration 702 is illustrated in FIG. 7 by those components within the inner dashed line.

Computing device 700 may have additional features or functionality, and additional interfaces to facilitate communications between basic configuration 702 and any required devices and interfaces. For example, a bus/interface controller 730 may be used to facilitate communications between basic configuration 702 and one or more data storage devices 732 (which may include SSD memory chips 120 or 122) via a storage interface bus 734. Data storage devices 732 may be removable storage devices 736, non-removable storage devices 738, or a combination thereof Examples of removable storage and non-removable storage devices include magnetic disk devices such as flexible disk drives and hard-disk drives (HDDs), optical disk drives such as compact disk (CD) drives or digital versatile disk (DVDs) drives, solid state drives (SSDs), and tape drives to name a few. Example computer storage media may include volatile and nonvolatile, removable and non-removable media implemented in any method or technology for storage of information, such as computer readable instructions, data structures, program modules, or other data.

System memory 706, removable storage devices 736 and non-removable storage devices 738 are examples of computer storage media. Computer storage media includes, but is not limited to, RAM, ROM, EEPROM, flash memory or other memory technology, CD-ROM, digital versatile disks (DVDs) or other optical storage, magnetic cassettes, magnetic tape, magnetic disk storage or other magnetic storage devices, or any other medium which may be used to store the desired information and which may be accessed by computing device 700. Any such computer storage media may be part of computing device 700.

Computing device 700 may also include an interface bus 740 for facilitating communication from various interface devices (e.g., output devices 742, peripheral interfaces 744, and communication devices 746) to basic configuration 702 via bus/interface controller 730. Example output devices 742 include a graphics processing unit 748 and an audio processing unit 750, which may be configured to communicate to various external devices such as a display or speakers via one or more A/V ports 752. Example peripheral interfaces 744 include a serial interface controller 754 or a parallel interface controller 756, which may be configured to communicate with external devices such as input devices (e.g., keyboard, mouse, pen, voice input device, touch input device, etc.) or other peripheral devices (e.g., printer, scanner, etc.) via one or more I/O ports 758. An example communication device 746 includes a network controller 760, which may be arranged to facilitate communications with one or more other computing devices 762 over a network communication link via one or more communication ports 764.

The network communication link may be one example of a communication media. Communication media may typically be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR) and other wireless media. The term computer readable media as used herein may include both storage media and communication media.

Computing device 700 may be implemented as a portion of a small-form factor portable (or mobile) electronic device such as a cell phone, a personal data assistant (PDA), a personal media player device, a wireless web-watch device, a personal headset device, an application specific device, or a hybrid device that include any of the above functions. Computing device 700 may also be implemented as a personal computer including both laptop computer and non-laptop computer configurations.

The present disclosure is not to be limited in terms of the particular embodiments described in this application, which are intended as illustrations of various aspects. Many modifications and variations can be made without departing from its spirit and scope. Functionally equivalent methods and apparatuses within the scope of the disclosure, in addition to those enumerated herein, are possible from the foregoing descriptions. Such modifications and variations are intended to fall within the scope of the appended claims. The present disclosure is to be limited only by the terms of the appended claims, along with the full scope of equivalents to which such claims are entitled. This disclosure is not limited to particular methods, reagents, compounds compositions or biological systems, which can, of course, vary. The terminology used herein is for the purpose of describing particular embodiments only, and is not intended to be limiting.

With respect to the use of substantially any plural and/or singular terms herein, one can translate from the plural to the singular and/or from the singular to the plural as is appropriate to the context and/or application. The various singular/plural permutations may be expressly set forth herein for sake of clarity.

In general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). If a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended to mean “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended to mean e.g., “a system having at least one of A, B, or C” would include but not be limited to systems that have A alone, B alone, C alone, A and B together, A and C together, B and C together, and/or A, B, and C together, etc. Virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, the disclosure is also thereby described in terms of any individual member or subgroup of members of the Markush group.

For any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. All language such as “up to,” “at least,” “greater than,” “less than,” and the like include the number recited and refer to ranges which can be subsequently broken down into subranges as discussed above. Finally, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments are possible. The various aspects and embodiments disclosed herein are for purposes of illustration and are not intended to be limiting, with the true scope and spirit being indicated by the following claims.

1. A method to decode data read from a memory, the method comprising:
storing coded data in a buffer;
calculating, by a bit flip module, a parity check syndrome vector based on the coded data and based on a parity check matrix, wherein the parity check syndrome vector includes unsatisfied bits;
storing the parity check syndrome vector in the buffer;
calculating a first bit flip threshold based on a feature of the parity check matrix;
determining, based on the parity check syndrome vector, a first number of unsatisfied parity checks participated in by a first bit of the coded data;
comparing the first number of unsatisfied parity checks to the first bit flip threshold;
flipping the first bit in response to the first number of unsatisfied parity checks for the first bit being greater than the first bit flip threshold;
updating the first bit flip threshold to produce a second bit flip threshold before determining a second number of unsatisfied parity checks participated in by a second bit of the coded data;
determining, based on the parity check syndrome vector, the second number of unsatisfied parity checks participated in by the second bit of the coded data; and
comparing the second number of unsatisfied parity checks to the second bit flip threshold.

2. (canceled)

3. The method of claim 1, wherein updating the first bit flip threshold to produce the second bit flip threshold comprises increasing the first bit flip threshold in response to the first number of unsatisfied parity checks participated in by the first bit being greater than the first bit flip threshold.

4. The method of claim 1, wherein updating the first bit flip threshold to produce the second bit flip threshold comprises decreasing the first bit flip threshold in response to the first number of unsatisfied parity checks being less than the first bit flip threshold.

5. The method of claim 1, further comprising:
flipping the second bit in response to the second number of unsatisfied parity checks being greater than or equal to the second bit flip threshold.

6. The method of claim 1, wherein:
the parity check syndrome vector includes a first parity check syndrome vector;
flipping the first bit produces decoded data; and
the method further comprises:
calculating, by the bit flip module, a second parity check syndrome vector based on the decoded data and the parity check matrix; and
flipping an other bit of the decoded data in response to a third number of unsatisfied parity checks for the other bit in the decoded data being greater than or equal to the second bit flip threshold.

7. The method of claim 1, wherein the feature of the parity check matrix includes a column weight.

8. The method of claim 1, wherein determining the first number of unsatisfied parity checks participated in by the first bit includes counting binary 1 values in unsatisfied rows of the parity check matrix, and wherein the unsatisfied rows of the parity check matrix are determined based on the parity check syndrome vector.

9. A memory controller, comprising:
a bit flip module; and
a buffer configured to be in communication with the bit flip module and to store coded data;
the bit flip module effective to:
calculate a parity check syndrome vector based on the coded data stored in the buffer and based on a parity check matrix, wherein the parity check syndrome vector includes unsatisfied bits;
calculate a first bit flip threshold based on a feature of the parity check matrix;
determine, based on the parity check syndrome vector, a first number of unsatisfied parity checks participated in by a first bit of the coded data;
compare the first number of unsatisfied parity checks to the first bit flip threshold
flip the first bit in response to the first number of unsatisfied parity checks for the first bit being greater than or equal to the first bit flip threshold;
update the first bit flip threshold to produce a second bit flip threshold before a determination of a second number of unsatisfied parity checks participated in by a second bit of the coded data;
determine, based on the parity check syndrome vector, the second number of unsatisfied parity checks participated in by the second bit of the coded data; and
compare the second number of unsatisfied parity checks to the second bit flip threshold.

10. (canceled)

11. The memory controller of claim 11, wherein to update the first bit flip threshold to produce the second bit flip threshold, the bit flip module is effective to increase the first bit flip threshold in response to the first number of unsatisfied parity checks participated in by the first bit being greater than the first bit flip threshold.

12. The memory controller of claim 11, wherein to update the first bit flip threshold to produce the second bit flip threshold, the bit flip module is effective to decrease the first bit flip threshold in response to the first number of unsatisfied parity checks being less than the first bit flip threshold.

13. The memory controller of claim 9, wherein
the bit flip module is further effective to:
flip the second bit in response to the second number of unsatisfied parity checks being greater than or equal to the second bit flip threshold.

14. The memory controller of claim 9, wherein:
the parity check syndrome vector includes a first parity check syndrome vector;
the flip of the first bit produces decoded data; and
the bit flip module is further effective to:
calculate a second parity check syndrome vector based on the decoded data and the parity check matrix; and
flip an other bit of the decoded data in response to a third number of unsatisfied parity checks for the other bit in the decoded data being greater than or equal to the second bit flip threshold.

15. The memory controller of claim 9, wherein the feature of the parity check matrix includes a column weight.

16. The memory controller of claim 9, wherein the determined first number of unsatisfied parity checks participated in by the first bit includes a count of binary 1 values in unsatisfied rows of the parity check matrix, and wherein the unsatisfied rows of the parity check matrix are determined based on the parity check syndrome vector.

17. A memory device,. comprising:
a bit flip module;
a buffer configured to be in communication with the bit flip module; and
a memory chip configured to be in communication with the bit flip module, wherein the memory chip is effective to store coded data;
the bit flip module effective to:
receive the coded data from the memory chip;
calculate a parity check syndrome vector based on the coded data and based on a parity check matrix, wherein the parity check syndrome vector includes indications of unsatisfied rows of the parity check matrix;
store the parity check syndrome vector in the buffer;
calculate a first bit flip threshold based on a feature of the parity check matrix;
determine, based on the parity check syndrome vector, a first number of unsatisfied parity checks participated in by a first bit of the coded data;
flip the first bit in response to the first number of unsatisfied parity checks for the first bit being greater than or equal to the first bit flip threshold;
update the first bit flip threshold to produce a second bit flip threshold before a determination of a second number of unsatisfied parity checks participated in by a second bit of the coded data;
determine, based on the parity check syndrome vector, the second number of unsatisfied parity checks participated in by the second bit of the coded data; and
compare the second number of unsatisfied parity checks to the second bit flip threshold.

18. The memory device of claim 17, wherein the bit flip module is further effective to update the first bit flip threshold to produce the second bit flip threshold in response to the first number of unsatisfied parity checks participated in by the first bit being greater than the first bit flip threshold or in response to the second number of unsatisfied parity checks being less than the speculated bit flip threshold.

19. The memory device of claim 17, wherein:
the feature of the parity check matrix includes a column weight;
and
the bit flip module is further effective to:
flip the second bit in response to the second number of unsatisfied parity checks being greater than or equal to the second flip bit threshold.

20. The memory device of claim 17, wherein:
the feature of the parity check matrix includes a column weight;
the parity check syndrome vector includes a first parity check syndrome vector;
the flip of the first bit produces decoded data; and
the bit flip module is further effective to:
calculate a second parity check syndrome vector based on the decoded data and the parity check matrix; and
flip an other bit of the decoded data in response to a third number of unsatisfied parity checks for the other bit in the decoded data being greater than or equal to the second bit flip threshold.
